(19) United States
(12) Patent Application Publication
(10) Pub. No.: US 2007/0108612 A1
(43) Pub. Date: May 17, 2007

(54) Chip structure and manufacturing method of the same

(75) Inventors: Chueh-An Hsieh, Kaohsiung (TW); Li-Cheng Tai, Kaohsiung (TW); Shyh-Ing Wu, Kaohsiung (TW); Shih-Kuang Chen, Kaohsiung (TW)

Correspondence Address: BIRCH STEWART KOLASCH & BIRCH, PO BOX 747, FALLS CHURCH, VA, 22040-0747, US

(73) Assignee: Advanced Semiconductor Engineering, Inc.

(21) Appl. No.: 11/511,429

(22) Filed: Aug. 29, 2006

(30) Foreign Application Priority Data
Nov. 15, 2005 (TW) 94140163

(51) Int. Cl. H01L 23/48

(52) U.S. Cl. 257/738

(57) ABSTRACT

A chip structure and a manufacturing method of the same. The chip structure includes a base, a pad, a first passivation layer, a second passivation layer and a bump. The pad is formed on the base. The first passivation layer is formed on the base exposing the pad. The second passivation layer formed on the first passivation layer has a passivation layer opening which is positioned above the pad. The bump is formed on the pad, and a part of the bump is disposed inside the passivation layer opening. The width at the bottom of the passivation layer opening is larger than the width at the top of the passivation layer opening, such that the bump is firmly fixed by the second protection layer.

This application claims the benefit of Taiwan application Serial No. 094140163, filed Nov. 15, 2005, the subject matter of which is incorporated herein by reference.

### BACKGROUND OF THE INVENTION

1. Field of the Invention

The invention relates in general to a chip structure and a manufacturing method of the same, and more particularly to an anti-stress chip structure and a manufacturing method of the same.

2. Description of the Related Art

Referring to FIGS. 1A˜1G, a conventional process of forming a chip structure is shown. The formation of chip structure includes the following processes. Firstly, as shown in FIG. 1A, a first passivation layer 103 is formed on a base 101, and a pad 105 is exposed. Next, a second passivation layer 107 is formed on the first passivation layer 103, and a passivation layer opening 109 is formed by applying exposure and development. Next, as shown in FIG. 1C, an under bump metallurgy (UBM) layer 111 is deposited on the first passivation layer 103, and then the UBM layer 111 is patterned. As shown in FIG. 1D, a first photo-resist layer 113 is further formed on the UBM layer 111. Then, as shown in FIG. 1E, the UBM layer 111 is etched, and the first photo-resist layer 113 is removed. Then, as shown in FIG. 1F, a second photo-resist layer 118 is formed on the second passivation layer 107, and a conductive material 119 such as solder paste is filled inside the passivation layer opening 109. Lastly, as shown in FIG. 1G, the conductive material 119 is reflown to form a bump 123, and the second photo-resist layer 118 is removed to form the chip structure 100.

After the chip structure 100 is formed, the reliability of the chip structure 100 is tested. The reliability test includes factors such as temperature change, pressure change and mechanic change, and must be tested periodically and repeatedly. The chip structure 100 is commonly found to have detachment between the bump 123 and the UBM layer 111 or between the UBM layer 111 and the pad 105. This is because the coefficients of thermal expansion (CTS) among the bump 123, the UBM layer 111 and the pad 105 dismatch, therefore the bump 123, the UBM layer 111 and the pad 105 are likely to be separated by the generated stress. That is to say, for the conventional chip structure 100, the adhesion among the bump 123, the UBM layer 111 and the pad 105 are insufficient to resist the separating stress which occurs due to the change in temperature, pressure and mechanic characteristics during the reliability test. Consequently, product reliability and product competiveness are jeopardized.

### SUMMARY OF THE INVENTION

It is therefore an object of the invention to provide a flip chip structure and manufacturing method of the same capable of improving anti-stress and reliability of package product.

The invention achieves the above-identified object by providing a chip structure including a base, a pad, a first passivation layer, a second passivation layer and a bump. The pad is formed on the base. The first passivation layer is formed on the base exposing the pad. The second passivation layer formed on the first passivation layer has a passivation layer opening which is positioned above the pad. The bump is formed on the pad, and a part of the bump is disposed inside the passivation layer opening. The width at the bottom of the passivation layer opening is larger than the width at the top of the passivation layer opening, such that the bump is firmly fixed by the second protection layer.

The invention further achieves the above-identified object by providing a chip structure including a base, a pad, a first passivation layer, a second passivation layer, an UBM layer and a bump. The pad is formed on the base. The first passivation layer is formed on the base exposing the pad. The second passivation layer formed on the first passivation layer has a passivation layer opening, which is positioned above the pad. A part of the UBM layer is formed on the second passivation layer while another part of the UBM layer is formed on the pad, and the part formed on the second passivation layer is separate from the part formed on the pad. The bump is formed on the UBM layer, and a part of the bump is filled inside the passivation layer opening. The width at the bottom of the passivation layer opening is larger than the width at the top of the passivation layer opening, such that the bump is firmly fixed by the second protection layer.

The invention further achieves the above-identified object by providing a method of manufacturing chip structure. The method includes the following steps. Firstly, a base is provided. Then, a first passivation layer and a pad are formed on the base, and the pad is exposed outside the first passivation layer. Next, a second passivation layer having a passivation layer opening for exposing the pad is formed on the first passivation layer. The width at the bottom of the passivation layer opening is larger than the width at the top of the passivation layer opening. Lastly, a bump is formed, a part of the bump is disposed inside the passivation layer opening, and the bump is electrically connected to the pad.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIGS. 1A˜1G illustrate a conventional process of forming a chip structure;

FIGS. 2A˜2H illustrate the process of forming a chip structure;

FIG. 3 illustrates the formation of an undercut on a second passivation layer; and

FIG. 4 is a flowchart of forming a chip structure.

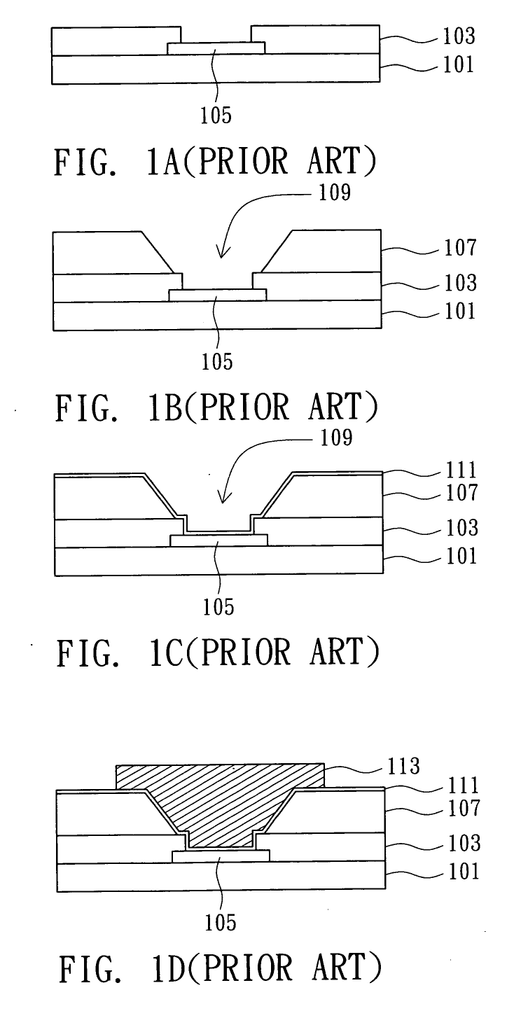

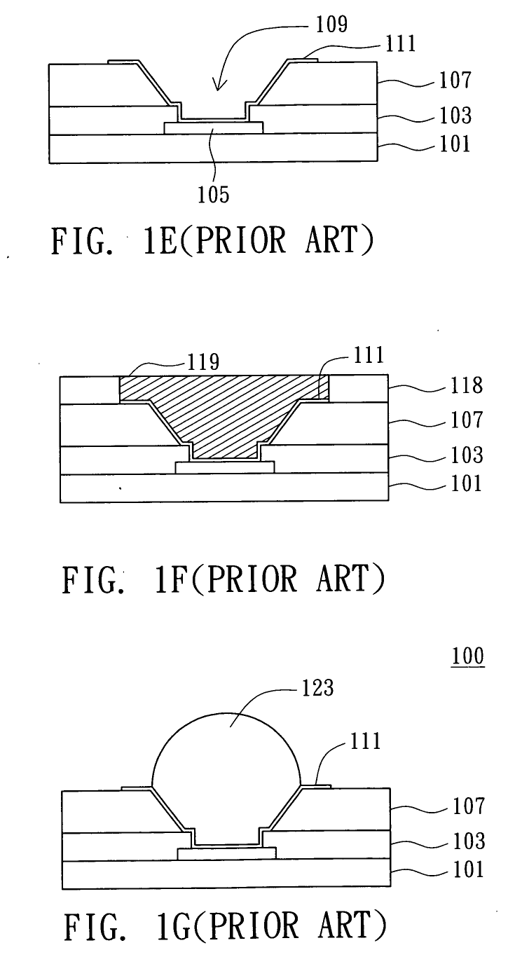

### DETAILED DESCRIPTION OF THE INVENTION

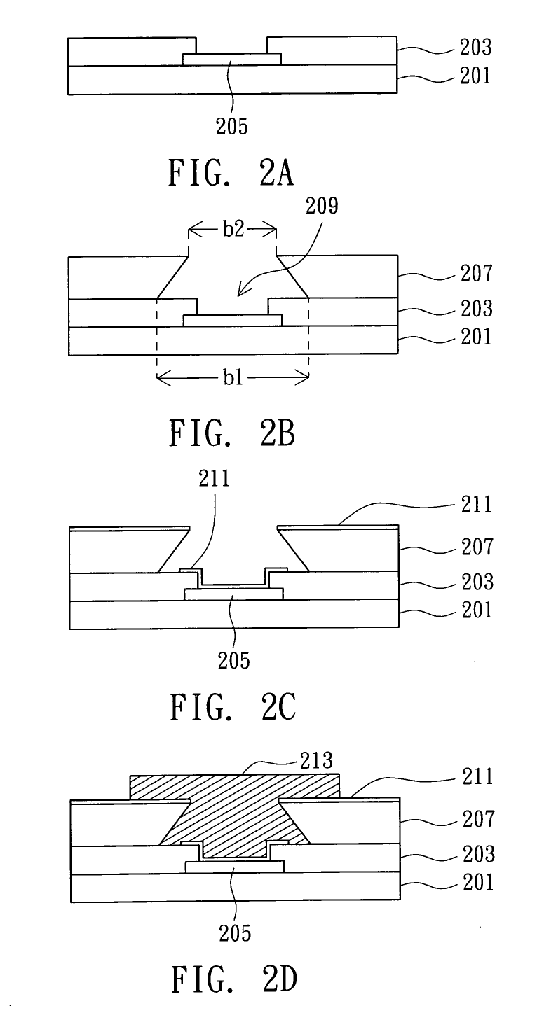

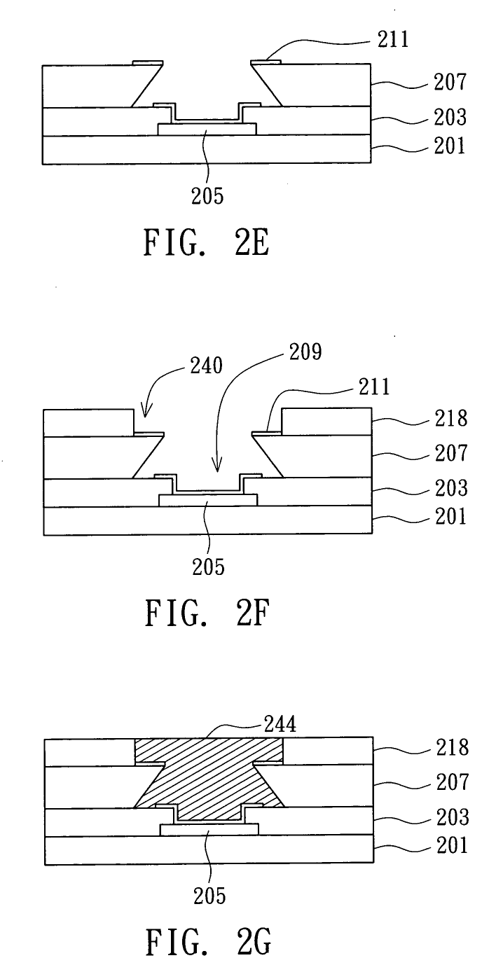

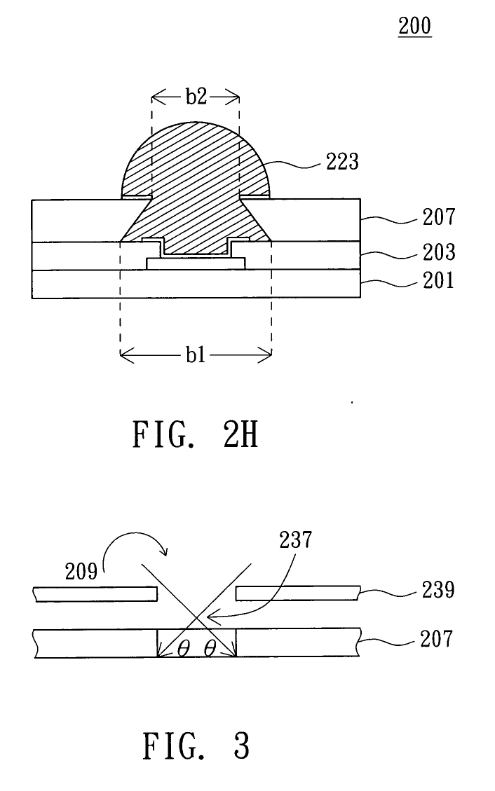

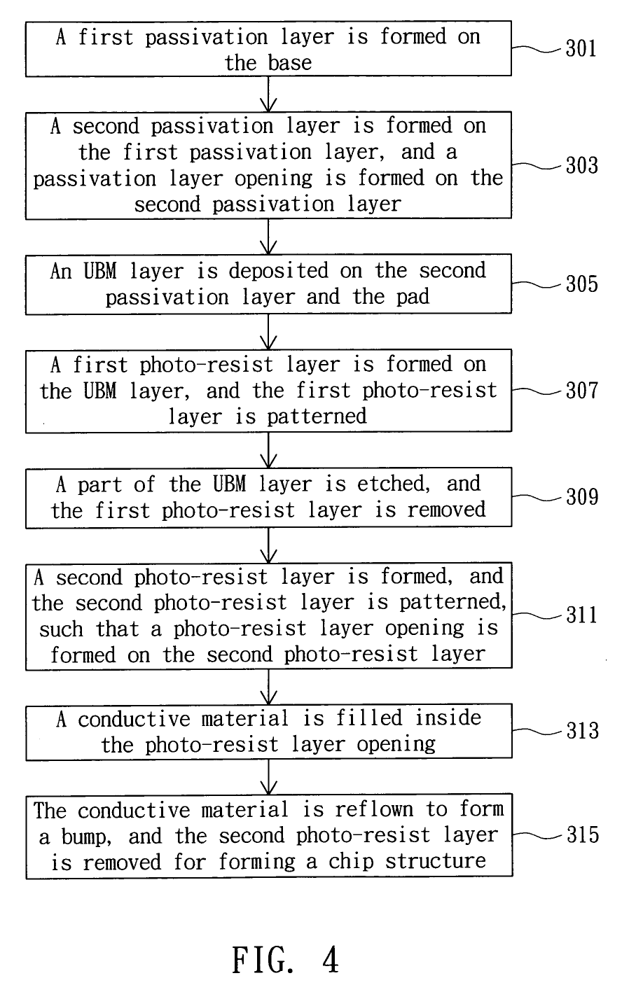

Referring to FIGS. 2A˜2H and FIG. 4. FIG. 2A to FIG. 2H illustrate the process of forming a chip structure. FIG. 4 is a flowchart of forming a chip structure. As shown in FIG. 2A, the method begins at the step 301, a first passivation layer 203 is formed on the base 201 exposing the pad 205. The material of the pad 205 normally includes aluminum or copper whereby the pad 205 is electrically connected to an external circuit. The first passivation layer 203 is for protecting the base 201 and leveling the surface. Next, proceed to step 303, as shown in FIG. 2B, a second passivation layer 207 is formed on the first passivation layer 203, and a passivation layer opening 209 is formed on the second passivation layer 207. The width b1 at the bottom of the passivation layer opening 209 is larger than the width b2 at the top of the passivation layer opening 209 so that an undercut is formed. The material of the second passivation layer 207 includes photosensitive polyimide capable of absorbing stress and serving as a buffer. Then, proceed to the step 305, as shown in FIG. 2C, an UBM layer 211 is deposited on the second passivation layer 207 and the pad 205. Since the passivation layer opening 209 has an undercut, when the UBM layer 211 is deposited, the UBM layer 211 on the second passivation layer 207 is not connected to the UBM layer 211 on the pad 205. The UBM layer 211 normally includes an adhesion layer, a barrier layer and a wetting layer (not shown). The adhesion layer provides excellent adhesion to the pad 205 and the first passivation layer 203. The material of the adhesion layer includes aluminum, titanium, chromium, or tungsten titanium and so on. The barrier layer prevents the occurrence of diffusion between the bump 223 (not shown in FIG. 2H) and the pad 205. The material of the barrier layer includes nickel-vanadium, or nickel and so on. The wetting layer provides excellent adhesion between the UBM layer 211 and the bump 223. The material of the wetting layer includes copper, molybdenum, or platinum and so on.

Next, proceed to step 307, as shown in FIG. 2D, a first photo-resist layer 213 is formed on the UBM layer 211, and the first photo-resist layer 213 is patterned. Then, proceed to the step 309, as shown in FIG. 2E, a part of the UBM layer 211 is etched, and the first photo-resist layer 213 is removed. Next, proceed to the step 311, a second photo-resist layer 218 is formed, and the second photo-resist layer 218 is patterned, such that a photo-resist layer opening 240 is formed on the second photo-resist layer 218. Then, proceed to the step 313, a conductive material 244 is filled inside the photo-resist layer opening 240. Examples of the conductive material 244 include solder paste. The conductive material 244 is preferably filled inside the photo-resist layer opening 240 by printing. Lastly, proceed to the step 315, the conductive material 244 is reflown to form a bump 223, and the second photo-resist layer 218 is removed. Consequently, a chip structure 200 is formed.

As shown in FIG. 2H, the width b1 at the bottom of the passivation layer opening 209 is larger than the width b2 at the top of the passivation layer opening 209, so the cross-section of the passivation layer opening 209 is basically a trapezoid. Therefore, in the chip structure 200, the bottom of the bump 223 is firmly fixed inside the passivation layer opening 209. During the reliability test of the chip structure 200, the trapezoid shape of the passivation layer opening 209 enhances the anti-stress capability of the bump 223. The stress occurs due to the change in temperature and mechanic characteristics. The process of forming the trapezoid passivation layer opening 209 either by adjusting the focal distance of exposure apparatus or by applying over development is disclosed below.

Referring to FIG. 3, the formation of an undercut on a second passivation layer is shown. During the formation of each passivation layer opening 209, by adjusting the exposure apparatus, the light passes through a mask 239 and then is projected onto the second passivation layer 207. The focus of the light 237 is positioned above the second passivation layer 207 such that an acute angle θ is formed at the bottom of the second passivation layer 207. After a portion of the second passivation layer 207 is removed by developing, each passivation layer opening 209 is shaped into a trapezoid whose bottom is larger than the top. In addition, the second method is achieved by projecting the light onto the upper surface of the second passivation layer 207, the upper surface of the second passivation layer 207 receives more energy of the light than the bottom surface of the second passivation layer 207. By increasing the duration of exposure, the area removed at the bottom of the second passivation layer 207 is larger than the area removed at the top, so an undercut is formed on the second passivation layer 207.

According to the flip chip structure disclosed in the above embodiment of the invention, the width at the bottom of the passivation layer opening is larger than the width at the top of the passivation layer opening. Therefore, the second passivation layer retains and prevents the bump from separating the pad and the UBM layer. With the above structure, the anti-stress capability of the overall flip chip structure is enhanced and the product reliability is improved.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A chip structure, comprising:
a base;
a pad formed on the base;
a first passivation layer formed on the base exposing the pad;
a second passivation layer formed on the first passivation layer, wherein the second passivation layer has a passivation layer opening positioned above the pad; and
a bump formed on the pad, wherein a part of the bump is disposed inside the passivation layer opening;
wherein the width at the bottom of the passivation layer opening is larger than the width at the top of the passivation layer opening, such that the bump is firmly fixed by the second protection layer.

2. The chip structure according to claim 1, wherein the chip structure further comprises an under bump metallurgy (UBM) layer formed between the bump and the pad.

3. The chip structure according to claim 2, wherein the UBM layer further is formed between the bump and the second passivation layer.

4. The chip structure according to claim 1, wherein a cross-section of the passivation layer opening is basically a trapezoid.

5. The chip structure according to claim 1, wherein the material of the second passivation layer includes polyimide.

6. A method of manufacturing chip structure, comprising:
providing a base;
forming a first passivation layer and a pad on the base, wherein the pad is exposed outside the first passivation layer;
forming a second passivation layer on the first passivation layer, wherein the second passivation layer has a passivation layer opening for exposing the pad, the width at the bottom of the passivation layer opening is larger than the width at the top of the passivation layer opening; and
forming a bump, wherein a part of the bump is disposed inside the passivation layer opening, and the bump is electrically connected to the pad.

7. The method according to claim 6, wherein after the step of forming the second passivation layer on the first passivation layer but prior to the step of forming the bump inside the passivation layer opening, the method further comprises:
depositing an UBM layer on the second passivation layer and the pad;
forming a first photo-resist layer on the UBM layer, and patterning the first photo-resist layer; and
etching a part of the UBM layer, and removing the first photo-resist layer.

8. The method according to claim 7, wherein the step of forming the bump comprises:
forming a second photo-resist layer;
patterning the second photo-resist layer for enabling the second photo-resist layer to have a photo-resist layer opening positioned above the passivation layer opening;
filling a conductive material inside the photo-resist layer opening and the passivation layer opening; and
reflowing the conductive material, and removing the second photo-resist layer to form the bump.

9. The method according to claim 8, wherein in the step of filling the conductive material inside the photo-resist layer opening and the passivation layer opening, the conductive material is filled inside the photo-resist layer opening by printing.

10. The method according to claim 6, wherein the step of forming the second passivation layer comprises:
coating the second passivation layer on the first passivation layer, wherein the material of the second passivation layer includes photosensitive polyimide;
applying exposure to the second passivation layer by a mask; and
applying over development to the second passivation layer to form the passivation layer opening.

11. The method according to claim 6, wherein the step of applying exposure to the second passivation layer further comprises:
adjusting the focal distance of an exposure apparatus, wherein the focus of the light during exposure is positioned above the second passivation layer such that an acute angle is formed.

12. The method according to claim 11, wherein the step of applying development to the second passivation layer further comprises:
controlling the duration of developing the second passivation layer such that the area etched by the developing solution at the bottom of the second passivation layer is larger than the area etched by the developing solution at the top of the second passivation layer.

13. The method according to claim 12, wherein the step of forming the second passivation layer comprises:
coating the second passivation layer on the first passivation layer, wherein the material of the second passivation layer includes photosensitive polyimide;
applying exposure to the second passivation layer by a mask, wherein the focus of the light during exposure is positioned above the second passivation layer; and
applying development to the second passivation layer to form the passivation layer opening.

14. A chip structure, comprising:
a base;
a pad formed on the base;
a first passivation layer formed on the base exposing the pad;
a second passivation layer formed on the first passivation layer, the second passivation layer has a passivation layer opening, the passivation layer opening is positioned above the pad;
an UBM layer, wherein a part of the UBM layer is formed on the second passivation layer while another part of the UBM layer is formed on the pad, and the part formed on the second passivation layer is separate from the part formed on the pad; and
a bump formed on the UBM layer, wherein a part of the bump is disposed inside the passivation layer opening;
wherein the width at the bottom of the passivation layer opening is larger than the width at the top of the passivation layer opening, such that the bump is firmly fixed by the second protection layer.

15. The chip structure according to claim 14, wherein a cross-section of the passivation layer opening is basically a trapezoid.

16 The chip structure according to claim 14, wherein the material of the second passivation layer includes polyimide.
